(19) United States
(12) Patent Application Publication
(10) Pub. No.: US 2007/0126001 A1
(43) Pub. Date: Jun. 7, 2007

(54) Organic semiconductor device and method of fabricating the same

(76) Inventors: Sung-Yool Choi, Daejeon (KR); Min Ki Ryu, Seoul (KR); Ansoon Kim, Daejeon (KR); Chil Seong Ah, Daejeon (KR); Han Young Yu, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/497,057

(22) Filed: Aug. 1, 2006

(30) Foreign Application Priority Data
Dec. 5, 2005 (KR) 10-2005-0117712
Apr. 20, 2006 (KR) 10-2006-0035654

(51) Int. Cl. H01L 29/08

(52) U.S. Cl. 257/40

(57) ABSTRACT

An organic semiconductor device and a method of fabricating the same are provided. The device includes: a first electrode; an electron channel layer formed on the first electrode; and a second electrode formed on the electron channel layer, wherein the electron channel layer comprises: a lower organic layer formed on the first electrode; a nano-particle layer formed on the lower organic layer and including predetermined sizes of nano-particles that are spaced a predetermined distance apart from each other; and an upper organic layer formed over the nano-particle layer. Accordingly, a highly integrated organic semiconductor device can be fabricated by a simple fabrication process, and nonuniformity of devices due to threshold voltage characteristics and downsizing of the device can resolved, so that a semiconductor device having excellent performance can be implemented.

### CROSS-REFERENCE TO RELATED APPLICATION

This application claims priority to and the benefit of Korean Patent Applications Nos. 2005-117712 and 2006-35654, filed on Dec. 5, 2005 and Apr. 20, 2006, the disclosure of which is incorporated herein by reference in its entirety.

### BACKGROUND

1. Field of the Invention

The present invention relates to an organic semiconductor device and a method of fabricating the same, and more particularly, an organic semiconductor device and a method of fabricating the same including an electron channel layer having a nano-particle layer made of nano-particles.

2. Discussion of Related Art

Semiconductor device technology has developed to the point of implementation of a Giga-bit DRAM, and it can be expected that a 100 G bit or more integrated circuit will soon be implemented. As semiconductor devices become more integrated, they become smaller in size, more highly functionalized, and have increasingly high-speed, high capacity, high integration density and low power consumption. Furthermore, it can be expected that key components of a ubiquitous communication environment can be provided in the form of system-on-chip SoC.

In particular, in current nonvolatile memory technology, flash memories based on electric charge control are widely used. An operation voltage of a CMOS is used in current flash memories. In this case, the flash memory uses a voltage of 17 to 20V made by charge-pumping inner power (1.5 to 5V) for programming or erasing information. As a result of using such a high voltage, a tunneling oxide layer tends to break down. This deteriorates the reliability of the memory.

When a future flash memory is scaled down to the 65 nm node, a flash memory tunneling oxide layer should also be reduced in thickness. In this case, a fabrication process is very complicated because an equivalent oxide thickness should be considered in design to prevent breakdown of the tunneling oxide layer. Also, when the flash memory is scaled down to the 65 nm node or less, because of noise between cells, there is a limit to down-scaling a device and the operability of the device comes into question.

In addition, when the current flash memory operates at a low voltage to consume less power, it is difficult to obtain a sufficient margin of cell current device characteristics. Accordingly, there is need to develop a new concept of functional memory device which can replace the current flash memory and overcome its physical and electrical problems. In recent years, research into organic electron devices, which are expected to meet all demands regarding nonvolatile electron devices, has been actively progressing.

In IEDM 2003, Infineon Technologies AG reported a structure and device characteristics of a highly integrated nonvolatile memory using an organic material, but did not provide a detailed description. It was reported that a simple 1R type memory device having an organic thin film with a cross-point shaped structure disposed between lower and upper electrodes was formed using a patterning process or a dielectric spacer in order to reduce cross-talk between memory cells. And, it was also reported that I_{on/off} was about 10², and a data retention time was about 8 months.

UCLA disclosed a nonvolatile organic semiconductor device using an organic material/metal/organic multi-thin film showing electrical bistability. The device disclosed by UCLA will be described below with reference to FIGS. 1A to 1C.

FIG. 1A is a side cross-sectional view of a conventional organic semiconductor device, FIG. 1B illustrates an organic structure constituting the organic semiconductor device of FIG. 1A, and FIG. 1C is a graph showing voltage-current characteristics of the organic semiconductor device.

Referring to FIGS. 1A and 1B, the organic semiconductor device 100 has a multi-layer structure of a metal electrode 101, a first organic material 102, an intermediate metal layer 103, a second organic material 104, and a metal electrode 105. Referring to FIG. 1B, the organic materials 102 and 104 constituting the organic semiconductor device 100 are formed of 2-amino-4,5-imidazoledicarbonitrile (AIDCN), and the upper and lower metal electrodes 101 and 105 and the intermediate metal layer 103 are formed of Al. As shown in FIG. 1C, the organic semiconductor device 100 formed as described above has a significantly large I_{on/off} of 10⁴˜10⁵ and a data retention time of several months.

Also, L.P. Ma et al. explained in Applied Physics Letters, 82 (9), 1419 (2003), that electrical bistability induces a difference in electrical conductivity by electric charge stored in a nanostructure of an organic material and an intermediate metal layer. That is, when a thin film having a thickness of 5˜20 nm is deposited as the intermediate metal layer and the intermediate metal layer is arranged in the shape of nano-particles by heat generated in an organic material deposition process, the nano-particles become capable of storing charge. However, as described above, when the thin metal film is deposited and then thermally treated to form the nano-particles, uniform nano-particles generally cannot be obtained. Consequently, when the organic semiconductor device is miniaturized, nonuniformity between devices may result.

Theoretically, organic devices are favorable for integration because they occupy a smaller cell area (˜4F²) than existing devices. However, according to research findings so far, thermal and chemical stability of a polymer or an organic material are not guaranteed in device operation, and thus such materials fall short of the demands for use in a highly integrated device. Also, processing properties of organic materials are different from those of a conventional inorganic semiconductor device. Accordingly, processing techniques for integration of a polymer device that are suited to the properties of organic materials, such as patterning, deposition, etching and low-temperature electrode formation techniques, are required.

### SUMMARY OF THE INVENTION

The present invention is directed to an organic semiconductor device including an electron channel layer having a nano-particle layer uniformly formed using a nano-particle and a method of fabricating the same.

One aspect of the present invention is to provide an organic semiconductor device comprising: a first electrode; an electron channel layer formed on the first electrode; and a second electrode formed on the electron channel layer, wherein the electron channel layer includes: a lower organic layer formed on the first electrode; a nano-particle layer formed on the lower organic layer and including predetermined sizes of nano-particles that are spaced a predetermined distance apart from each other; and an upper organic layer formed over the nano-particle layer.

When a voltage is not applied from the external, the electron channel layer may maintain a high conductance state or a low conductance state. The electron channel layer may have switching characteristics, in which a high conductance state is converted to a low conductance state or vice versa, depending on a voltage applied from the external. The nano-particle may be formed of metal selected from the group consisting of Al, Au, Ag, Co, Ni, Fe or a combination thereof. The nano-particle may have a size of 1˜20 nm. The distance between the nano-particles may be within about 50%-150% of the diameter of the nano-particles. The organic semiconductor device may further comprise a monomer organic layer formed between the upper organic layer and the nano-particle layer and a monomer organic layer formed between the lower organic layer and the nano-particle layer.

Another aspect of the present invention is to provide a method of fabricating an organic semiconductor device, comprising the steps of: forming a first electrode; forming an electron channel layer on the first electrode, the electron channel layer including a nano-particle layer having predetermined sizes of nano-particles that are spaced a predetermined distance apart from each other, an upper organic layer formed over the nano-particle layer, and a lower organic layer below the nano-particle layer; and forming a second electrode on the electron channel layer.

The step of forming the electron channel layer may comprise the steps of: forming the lower organic layer on the first electrode; forming the nano-particle layer having predetermined sizes of nano-particles that are spaced a predetermined distance apart from each other on the lower organic layer; and forming the upper organic layer on the nano-particle layer. The nano-particle layer, the upper organic layer, and the lower organic layer may be formed by a Langmuir-Blodgett method. The nano-particles may be metal nano-particles consisting of Al, Au, Ag, Co, Ni, Fe or a combination thereof and formed to have a size of 1˜20 nm. The distance between the nano-particles may be within about 50%-150% of the diameter of the nano-particles. The upper and lower organic layers may have semiconductor or insulator properties and may be formed of an organic material having a band gap of 2eV or more. The first and second electrodes may be formed of Al, Cu, Au, Pt or doped silicon. The nano-particle may be formed by a spin coating method.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1A is a cross-sectional view of a conventional organic semiconductor device;

FIG. 1B illustrates an organic structure constituting the organic semiconductor device of FIG. 1A;

FIG. 1C is a graph showing voltage-current characteristics of the organic semiconductor device;

FIG. 2 illustrates the structure of an organic semiconductor device according to an exemplary embodiment of the invention;

FIG. 3A illustrates a process of fabricating a general layer using a Langmuir-Blodgett method;

FIG. 3B illustrates a detailed structure of an organic semiconductor device having a stacked LB layer and fabricated using the method of FIG. 3A; and

FIG. 4 is a graph showing the characteristics of the organic semiconductor device of FIG. 2.

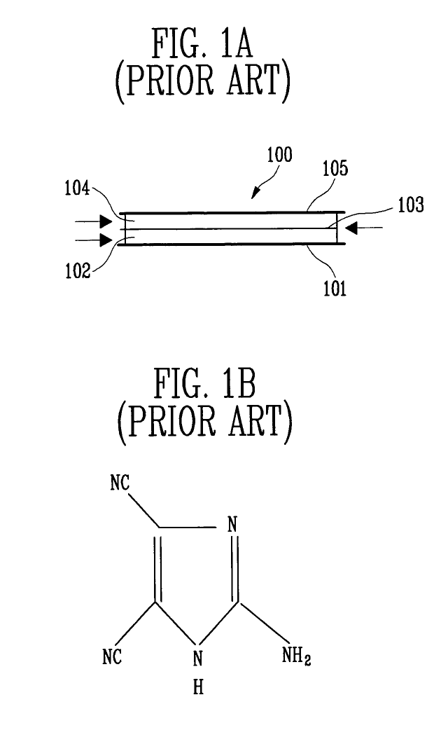

### DETAILED DESCRIPTION OF PREFERRED EMBODIMENTS

Hereinafter, an organic semiconductor device and a method of fabricating the same according to exemplary embodiments of the present invention will be described in detail with reference to the accompanying drawings.

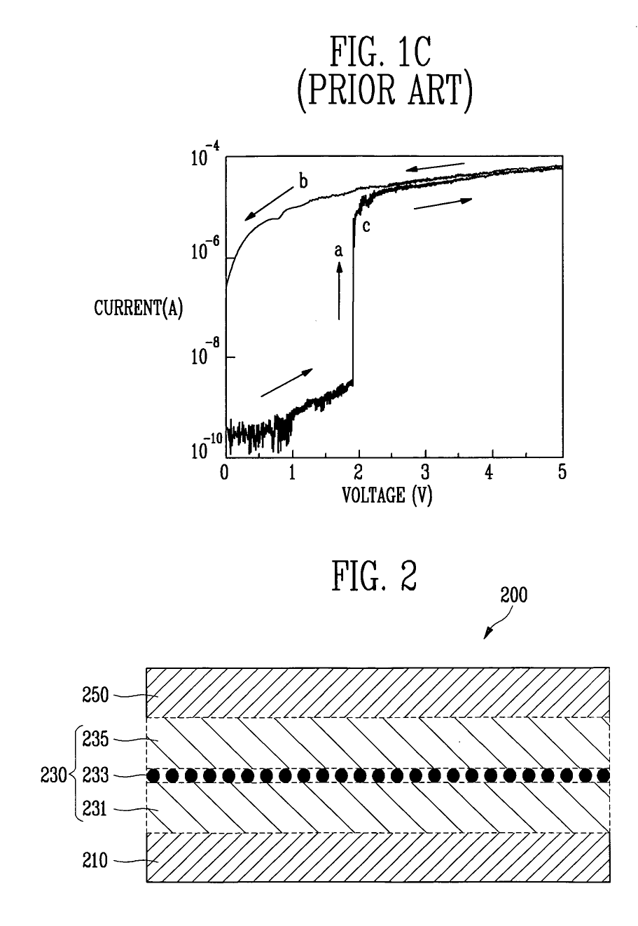

FIG. 2 illustrates the structure of an organic semiconductor device according to an exemplary embodiment of the present invention. Referring to FIG. 2, an organic semiconductor device 200 according to the present invention includes a first electrode 210, an electron channel layer 230 disposed on the first electrode 210, and a second electrode 250 disposed on the electron channel layer 230. The electron channel layer 230 includes a lower organic layer 231 disposed on the first electrode 210, a nano-particle layer 233 disposed on the lower organic layer 231, and an upper organic layer 235 disposed on the nano-particle layer 233.

To be specific, the first and second electrodes 210 and 250 may be formed of a general electrode material such as Al, Cu, Au or Pt, or doped silicon. Although not shown in FIG. 2, a monomer layer or a glue layer such as Ti or Cr, may be further disposed between the first electrode 210 and the lower organic layer 231, and between the upper organic layer 235 and the second electrode 250 to improve a contact between the organic layer and the electrode.

The lower and upper organic layers 231 and 235 may be formed of monomer or polymer, which has a dielectric property. Here, each thin film of the organic layers 231 and 235 formed of monomer or polymer may have a thickness deviation of 5% or less. To obtain these highly uniform organic layers 231 and 235, a Langmuir-Blodgett method, in which a monomer layer is formed on the surface of the water and accumulated on a substrate (not shown), is used. In the exemplary embodiment of the invention, the organic layers 231 and 235 having a thickness of about 1˜50 nm are used and the thin film of the organic layer has a thickness deviation of 5% or less.

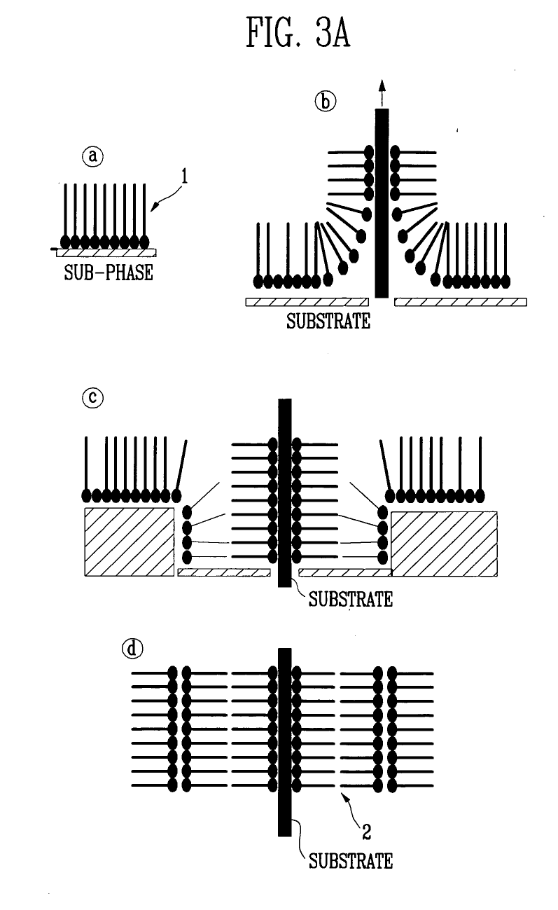

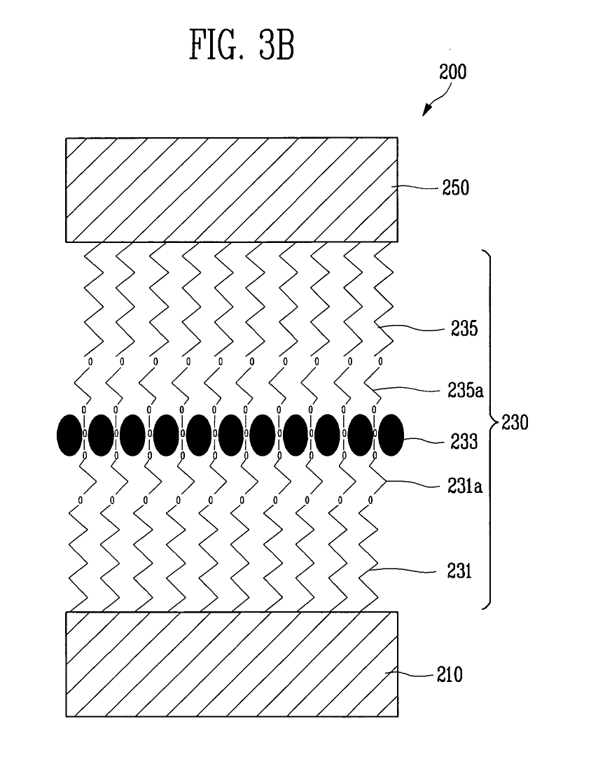

FIG. 3A illustrates a process of fabricating a general layer using a Langmuir-Blodgett method, and FIG. 3B illustrates a detailed structure of an organic semiconductor device fabricated using the method of FIG. 3A.

Referring to FIG. 3A, first, a monomer or polymer material dissolved in a hydrophobic solvent is dropped in a hydrophilic solution, e.g. water, to form an (organic) monomer layer 1, i.e., a Langmuir-Blodgett film LB (a), and the monomer layer is stacked on a substrate to form a monomer layer having a molecular unit (b). In process (b), it is shown that when the substrate is lifted up from a polymer solution, a molecular chain adsorbed on the surface of the substrate is aligned in one direction. Processes (c) and (d) show that when plural organic layers should be formed to increase the thickness of a thin film, a multi-layer 2 is formed by stacking LB layers several times.

Referring to FIG. 3B, an organic semiconductor device in which an LB layer is stacked using the LB method of FIG. 3 is illustrated. The organic semiconductor device 200 includes a pair of electrodes 210 and 250, and an electron channel layer 230 formed between the electrodes 210 and 250. The electron channel layer 230 is composed of a lower organic layer 231 formed on the electrode 210, a monomer organic layer 231a formed on the lower organic layer 231 by the LB method, a nano-particle layer 233 formed on the monomer organic layer 231a, a monomer organic layer 235a formed on the nano-particle layer 233 by the LB method, and an upper organic layer 235 formed on the monomer organic layer 235a.

The nano-particle layer 233 may be formed of Al, Au, Ag, Co, Ni, Fe, and so on. The nano-particle is functionalized to a material having a surfactant component for two-dimensional alignment (that is, uniform alignment between the monomer organic layers 231a and 235a) of the nano-particle layer 233. Here, the surfactant serves to change a hydrophilic nano-particle to a hydrophobic one, and in the embodiment, mercapto-oleic acid is used as the surfactant.

The nano-particle constituting the nano-particle layer 233 may have a size of 1˜20 nm, and the monomer layer of the nano-particle functionalized by the surfactant component is also stacked by an LB or spin coating method to form the nano-particle layer 233 between the organic layers 231 and 235. Meanwhile, a distance between the nano-particles of the nano-particle layer 233 can be controlled by the length of a surfactant. Ideally, the distance between the nano-particles is the same as the diameter of the nano-particles. However, operation of the device is not affected so long as the distance between the nano-particles is within about 50%-150% of the diameter of the nano-particles. In this embodiment, the electron channel layer 230 may have a thickness of about 1˜100 nm.

The electron channel layer 230 of the organic semiconductor device 200 fabricated by the above-mentioned method maintains a high conductance state and a low conductance state when a voltage is not applied to the electron channel layer 230, and has switching characteristics that a high conductance state is converted to a low conductance state or vise versa, depending on the voltage applied from the external. The switching characteristics of the organic semiconductor device according to the present invention will now be described with reference to the accompanied drawings.

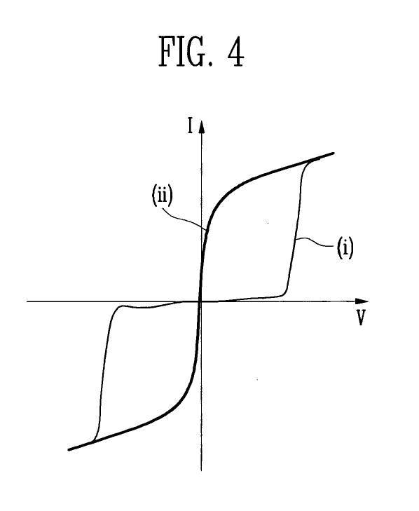

FIG. 4 is a graph illustrating switching characteristics of the organic semiconductor device of FIG. 3B. Referring to FIGS. 3B and 4, when a voltage is applied to the electrodes 210 and 250 which are disposed at both ends of the organic semiconductor device 200, current flows in a uniform direction, and the device 200 has a high conductance state (i) and a low conductance state (ii), and thus memory effect can be provided.

In operation of the organic semiconductor device 200, when a positive voltage is applied to the device with a threshold voltage Vt, the device is in the low conductance state. But when a voltage above Vt is applied, the device is converted into the high conductance state. When a voltage above Vt is applied, electrons pass an organic barrier serving as a dielectric material and are injected into a metal nano-particle. The electron channel layer 230 is converted into the high conductance state by the electrons injected into the metal nano-particle. Meanwhile, to convert the high conductance state into the low conductance state, a reverse voltage should be applied. Thus, when a voltage of about −Vt is applied, the high conductance state is converted into the low conductance state. The process can be repeatedly performed and each conductance state is maintained for a specific time or more. Accordingly, the organic semiconductor device can be used for a nonvolatile memory.

When the organic material has semiconductor or insulator properties (band gap is 2 eV or more), a sudden and reversible phase change between the high conductance state and the low conductance state may be provided, and when an inserted metal nano-particle has a size of about 1˜20 nm, charges can be stored enough at room temperature. Also, when a thin film is formed of a uniform nano-particle having a specific size, nonuniformity of the devices may be suppressed even if the device is scaled down.

The organic semiconductor device has channel characteristics in which a high conductance state is converted to a low conductance state or vice versa depending on an applied voltage and nonuniformity between the devices caused by the scale-down of the device can be suppressed by using uniform nano-particles, and thus the device according to this present invention can be utilized as an organic semiconductor device having excellent characteristics.

As described above, an organic semiconductor device including an electron channel layer having a nano-particle layer formed of uniform nano-particles has channel characteristics in which a high conductance state is converted to a low conductance state or vice versa depending on an applied voltage and nonuniformity between the devices caused by the scale-down of the device can be suppressed by using uniform nano-particles, and thus the device according to the present invention can be utilized as an organic semiconductor device having excellent characteristics.

Also, when a nano-particle having a specific size is used as a medium for storing charges, it is possible to change a distance between nano-particles to increase charge storing time, thereby significantly increasing retention time of stored information.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. An organic semiconductor device comprising:
a first electrode;
an electron channel layer formed on the first electrode; and
a second electrode formed on the electron channel layer,
wherein the electron channel layer includes: a lower organic layer formed on the first electrode; a nano-particle layer formed on the lower organic layer and including predetermined sizes of nano-particles that are spaced a predetermined distance apart from each other; and an upper organic layer formed over the nano-particle layer.

2. The device according to claim 1, wherein the electron channel layer maintains a high conductance state or a low conductance state, when a voltage is not applied from the external.

3. The device according to claim 1, wherein the electron channel layer has switching characteristics in which a high conductance state is converted to a low conductance state or vice versa, depending on a voltage applied from the external.

4. The device according to claim 1, wherein the nano-particle is formed of metal selected from the group consisting of Al, Au, Ag, Co, Ni, Fe or a combination thereof.

5. The device according to claim 1, wherein the nano-particle has a size of 1˜20 nm.

6. The device according to claim 5, wherein the distance between the nano-particles is within about 50%-150% of the diameter of the nano-particles.

7. The device according to claim 1, further comprising a monomer organic layer formed between the upper organic layer and the nano-particle layer.

8. The device according to claim 1, further comprising a monomer organic layer formed between the nano-particle layer and the lower organic layer.

9. A method of fabricating an organic semiconductor device, comprising the steps of:
forming a first electrode;
forming an electron channel layer on the first electrode, the electron channel layer including a nano-particle layer having predetermined sizes of nano-particles that are spaced a predetermined distance apart from each other, an upper organic layer formed over the nano-particle layer, and a lower organic layer below the nano-particle layer; and
forming a second electrode on the electron channel layer.

10. The method according to claim 9, wherein the step of forming the electron channel layer comprises the steps of:
forming the lower organic layer on the first electrode;
forming the nano-particle layer having predetermined sizes of nano-particles that are spaced a predetermined distance apart from each other on the lower organic layer; and
forming the upper organic layer on the nano-particle layer.

11. The method according to claim 9, wherein the nano-particle layer, the upper organic layer, and the lower organic layer are formed by a Langmuir-Blodgett method.

12. The method according to claim 9, wherein the nano-particle is formed of metal selected from the group consisting of Al, Au, Ag, Co, Ni, Fe or a combination thereof.

13. The method according to claim 9, wherein the nano-particle is has a size of 1˜20 nm.

14. The method according to claim 13, wherein the distance between the nano-particles is within about 50%-150% of the diameter of the nano-particles.

15. The method according to claim 9, wherein the upper and lower organic layers have semiconductor or insulator properties, and are formed of an organic material having a band gap of 2 eV or more.

16. The method according to claim 9, wherein the first and second electrodes are formed of Al, Cu, Au, Pt, or doped silicon.

17. The method according to claim 10, wherein the nano-particle is formed by a spin coating method.
